(19) United States
(12) Patent Application Publication
(10) Pub. No.: US 2026/0316017 A1
(43) Pub. Date: Oct. 15, 2026

(54) NITROGEN PREPARATION METHOD AND NITRO BEVERAGE DEVICE

(71) Applicant: JICUICHUANGXIN (SHENZHEN) TECH CO., LTD., Shenzhen (CN)

(72) Inventors: Siting Xiao, Shenzhen (CN); Tianyi Tan, Shenzhen (CN)

(21) Appl. No.: 19/647,970

(22) Filed: Apr. 15, 2026

(30) Foreign Application Priority Data
Apr. 15, 2025 (CN) 202510470548.0
Apr. 15, 2025 (CN) 202520714230.8

(51) Int. Cl. B01F 23/2361; B01D 53/047

(52) U.S. Cl. CPC B01F 23/2361; B01D 53/047; B01D 2256/10; B01D 2257/104; B01D 2257/80; B01D 2259/40003; B01D 2259/40009; B01D 2259/4525

(57) ABSTRACT

The present invention discloses a nitrogen preparation method and a nitro beverage device. The method includes drawing in and compressing air, removing impurities, and directing the filtered air to a first molecular sieve to generate nitrogen. After a preset time, the flow switches to a second molecular sieve for continuous nitrogen production. The nitrogen is output according to a user-defined pressure. By directly outputting nitrogen from the molecular sieves, the system eliminates the need for gas storage and buffer tanks, simplifying the structure and enabling immediate use of generated nitrogen. The two molecular sieves operate alternately under control of a control unit, ensuring continuous and stable nitrogen generation. This design improves efficiency, reduces system complexity, and enhances operational convenience, making it suitable for nitro beverage applications.

### CROSS REFERENCE TO RELATED APPLICATIONS

The present application claims the benefit of Chinese Patent Application No. 202510470548.0 and 202520714230.8 filed on Apr. 15, 2025, the contents of which are incorporated herein by reference in their entirety.

### TECHNICAL FIELD

The present invention belongs to the field of food science technologies, and specifically, relates to a nitrogen preparation method and a nitro beverage device.

### BACKGROUND

As an inert gas, when added to a beverage, nitrogen forms a unique silky and creamy texture. Therefore, foamy beverages are increasingly favored by consumers.

However, existing technologies for making foamy beverages usually require the use of large-volume devices, such as an air compressor, a refrigerated air dryer, and an air storage tank. This not only increases operation costs, but also impedes implementation of small-sized household devices.

### SUMMARY

In view of the foregoing problem, the present invention aims to provide a nitrogen preparation method and a nitro beverage device, to solve problems that existing nitrogen preparation apparatuses are complex in structure, are difficult to maintain, and have high costs.

According to an aspect of embodiments of this application, a nitrogen preparation method is provided, including the following steps:
drawing in air and compressing the air;
filtering out impurities in compressed air;
transmitting filtered air to a first molecular sieve via a first path to generate nitrogen;
switching, after preset time, to transmitting the filtered air to a second molecular sieve via a second path to generate nitrogen; and
outputting the nitrogen according to a user preset pressure value.
According to above optimization, the "outputting the nitrogen according to a user preset pressure value" further includes:
filtering the generated nitrogen;
controlling a flow direction and a flow rate of filtered nitrogen; and
detecting whether a pressure value of the nitrogen exceeds a preset safe pressure value.

According to above optimization, the nitrogen preparation method further includes:
automatically relieving pressure if a pressure value of the compressed air is greater than the preset safe pressure value.

According to another aspect of the embodiments of the present invention, a nitro beverage device is provided, configured to perform the nitrogen preparation method according to any one of the foregoing embodiments. The nitro beverage device includes: an air pump, configured to draw in air and compress the air; an oil-water separator, configured to filter out impurities in compressed air; a switching module, configured to transmit filtered air to a first molecular sieve via a first path, the switching module being further configured to switch, after preset time, to transmitting the filtered air to a second molecular sieve via a second path; and a nozzle and a gas cylinder that are detachably connected, the nozzle being configured to fill the nitrogen into the gas cylinder according to a user preset pressure value.

According to above optimization, a first three-way valve is disposed between the oil-water separator and the switching module, and the first three-way valve is connected to a pressure relief port; the first three-way valve transmits the filtered air to the switching module when responding to a start operating instruction of a user; and the first three-way valve is controlled, when responding to a stop instruction of a user, to cause the air drawn by the air pump to flow out through the pressure relief port.

According to above optimization, a second three-way valve is disposed between the first three-way valve and the switching module, the second three-way valve is connected to a safety valve, and the second three-way valve is further configured to transmit the air to the switching module; and the safety valve is configured to relieve pressure when a pressure of the air is greater than the preset safe pressure value.

According to above optimization, the first molecular sieve includes a first throttle valve, the second molecular sieve includes a second throttle valve, and the first throttle valve and the second throttle valve are connected to a third three-way valve; and during an absorption operation of the first molecular sieve, the separated nitrogen enters the nozzle via the third three-way valve, and/or enters the second molecular sieve sequentially via the third three-way valve and the second throttle valve; and during a release operation, the first molecular sieve releases oxygen and water vapors through an air exhaust.

According to above optimization, a filtering apparatus, a third throttle valve, and a pressure sensor are disposed between the third three-way valve and the nozzle; the filtering apparatus is configured to filter out impurities in the nitrogen; the third throttle valve is configured to control a pressure value of the nitrogen and control the nitrogen to be transmitted to the pressure sensor; and the pressure sensor configured to detect the pressure value of the nitrogen.

According to above optimization, a cooling pipe is further disposed between the air pump and the oil-water separator, and the cooling pipe is configured to cool the air compressed by the air pump.

According to above optimization, the nitro beverage device further includes a control panel and a control unit, the control panel is configured to generate a user instruction, and the control unit is configured to control start/stop or power-off of each component to respond to the user instruction; and the control panel includes an operation key and a display panel; the operation key is used for a user to set the user preset pressure value and start or pause operating of a device; and the display panel is configured to display a device state and the user preset pressure value.

Beneficial effects of this application are as follows: In this application, by directly outputting the nitrogen generated by the first molecular sieve and the second molecular sieve through the air outlet, setting of gas storage tanks is reduced, an operating mode in which the nitrogen is used right after being generated is implemented, and an internal structure is simplified while high efficiency is ensured, so that the operations are more convenient. In addition, the first molecular sieve and the second molecular sieve operate alternately under time sequence control of the control unit, and one performs an absorption operation and the other performs release and regeneration operations, thereby ensuring sustainability of the generation of the nitrogen.

### BRIEF DESCRIPTION OF THE DRAWINGS

To describe technical solutions of the embodiments of this application more clearly, the following briefly introduces the accompanying drawings required for the embodiments. Apparently, the accompanying drawings in the following descriptions show only some embodiments of this application, and a person of ordinary skill in the art may still derive other drawings from these accompanying drawings without creative efforts.

FIG. 1 is a process flowchart of a nitro beverage device according to an embodiment of the present invention;

FIG. 2 is a schematic structural diagram of a nitro beverage device according to an embodiment of the present invention;

FIG. 3 is a schematic diagram of an exploded structure of a nitro beverage device according to an embodiment of the present invention;

FIG. 4 is a schematic diagram of matching between a nitro beverage device and a gas cylinder according to an embodiment of the present invention;

FIG. 5 is a schematic diagram of an internal structure of a nitro beverage device according to an embodiment of the present invention;

FIG. 6 is a step flowchart of a nitrogen preparation method according to an embodiment of the present invention; and

FIG. 7 is another step flowchart of a nitrogen preparation method according to an embodiment of the present invention.

It should be noted that the accompanying drawings are not necessarily drawn to scale, but are only shown in a schematic manner that does not affect understanding of the reader.

Reference numerals in the accompanying drawings in the specification:

100: Nitro beverage device; 110: air pump; 120: cooling pipe; 130: oil-water separator; 140: first molecular sieve; 150: second molecular sieve; 160: carrier platform; 170: nozzle; 180: control panel; 181: display panel; 182: operation key; 190: first electromagnetic valve; and 200: gas cylinder.

### DETAILED DESCRIPTION

The technical solutions in the embodiments of this application are clearly and completely described in the following with reference to the accompanying drawings in the embodiments of this application. Apparently, the described embodiments are merely some rather than all of the embodiments of this application. All other embodiments obtained by a person of ordinary skill in the art based on the embodiments of this application without creative efforts shall fall within the protection scope of this application.

In this application, orientation or position relationships indicated by the terms such as "up", "down", "left", "right", "front", "rear", "top, "bottom", ""inner", "outer", "middle", "vertical", "horizontal", "longitudinal", and "transverse" are based on orientation or position relationships shown in the accompanying drawings. These terms are mainly intended to better describe this application and the embodiments of this application, and are not intended to limit that the indicated apparatus, element, or component must have a specific orientation, or be constructed and operated in a specific orientation.

In addition, some of the terms may be used for expressing other meanings besides representing an orientation or a position relationship. For example, the term "on" may also be used for representing a dependency relationship or a connection relationship in some cases. A person of ordinary skill in the art may understand the specific meanings of these terms in the present application according to specific situations.

In addition, the terms "install", "set", "dispose", "connect", and "connected" should be understood in a broad sense. For example, these terms may be understood as a fixing connection, a detachable connection, an integral connection, a mechanical connection, an electrical connection, a direct connection, an indirect connection by using an intermediate medium, or communication between interiors of two apparatuses, elements, or components. A person of ordinary skill in the art may understand the specific meanings of the foregoing terms in this application according to specific situations.

In addition, the terms "first", "second", and the like are mainly used for distinguishing different apparatuses, elements, or components (specific types and structures of which may be the same or may be different), and are not used for indicating or implying relative importance and a quantity of the indicated apparatuses, elements, or components. "A plurality of" means two or more than two unless otherwise specified.

It should be further understood that, the terms used in this specification of this application are only for the purpose of illustrating specific embodiments, and are not intended to limit this application. The terms "a", "one", and "the" of singular forms used in this specification and the appended claims of this application are also intended to include plural forms, unless otherwise specified in the context clearly.

It should be further understood that, the term "and/or" used in this specification and the appended claims of this application refers to and includes any and all possible combinations of one or more of the associated listed items.

The foamy beverage generally refers to a type of beverage in which nitrogen are injected to change mouthfeel and appearance of the beverage. Nitro beverages or nitro drinks are beverages filled with nitrogen, and the beverage is different from a conventional carbonated beverage because bubbles generated by nitrogen are finer and smoother, and form a smooth froth layer on the surface of the beverage. Such a beverage can provide a unique mouthfeel experience, which is referred to as a "creamy" mouthfeel, and a froth cascade (that is, a layer of the froth moving from top to bottom) of the nitro beverage lasts for longer time, increasing visual attractiveness of the beverage. Nitro cold brew coffee is one type of the nitro beverages, and is briefly referred to as nitro coffee or nitro cold brew. This is a coffee-containing nitro beverage filled with nitrogen.

An existing foamy beverage production technology usually has a large volume and has high operating costs. To resolve this problem, Chinese Patent 202020768232.2 discloses a small-sized integrated nitrogen production machine. Although the problem of high costs is resolved, components such as a nitrogen storage tank and a buffer tank are still required to store produced nitrogen in advance. However, because of disposition of these components, effects of compacting the structure, producing nitrogen whenever the nitrogen needs to be used, and facilitating user operations and utilization cannot be achieved to some extent.

In addition, in the foamy beverage manufacturing technology, generation and injection of the nitrogen are a key process, and different pressure settings cause different injection speeds, thereby generating bubbles with different characteristics. For example, a low pressure may generate finer and more lasting froth, and a high pressure may generate richer and faster froth. Therefore, how to satisfy requirements of different users on generation and injection of nitrogen, to achieve particular mouthfeel and visual presentation, and also make operations convenient and rapid is a problem needing to be resolved in the technical field of foamy beverage manufacturing.

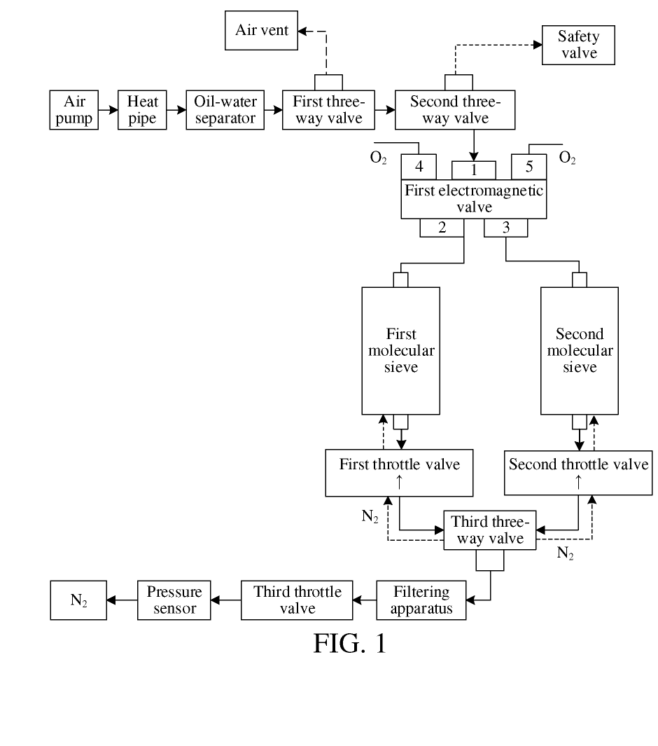

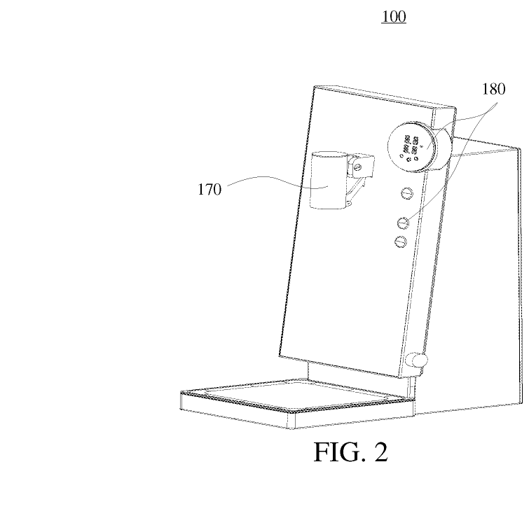

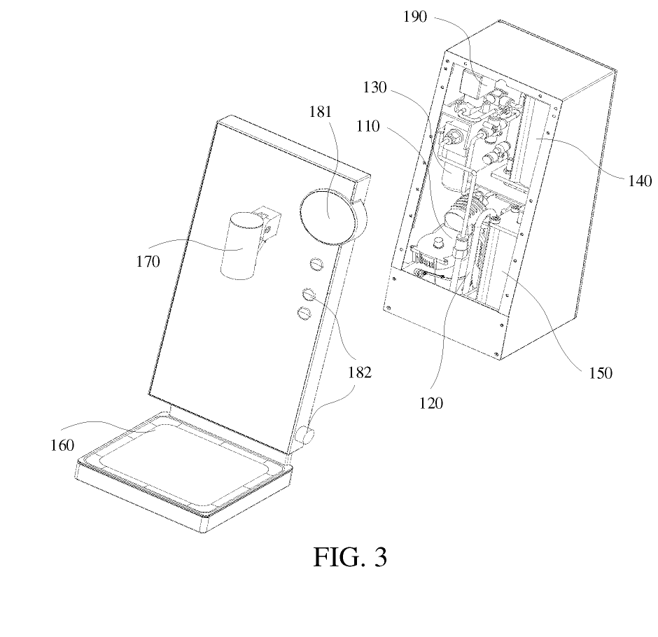

In view of the foregoing problem, this application provides a nitro beverage device. As shown in FIGS. 1-4, the nitro beverage device includes: a carrier platform 160, configured to place a gas cylinder 200; a control panel 180, configured to be operated by a user to send an instruction; and a nozzle 170, configured to connect to the gas cylinder 200, where nitrogen is injected from the nozzle 170 into the gas cylinder according to a user preset pressure value, and the gas cylinder 200 is detachably connected to the nozzle 170.

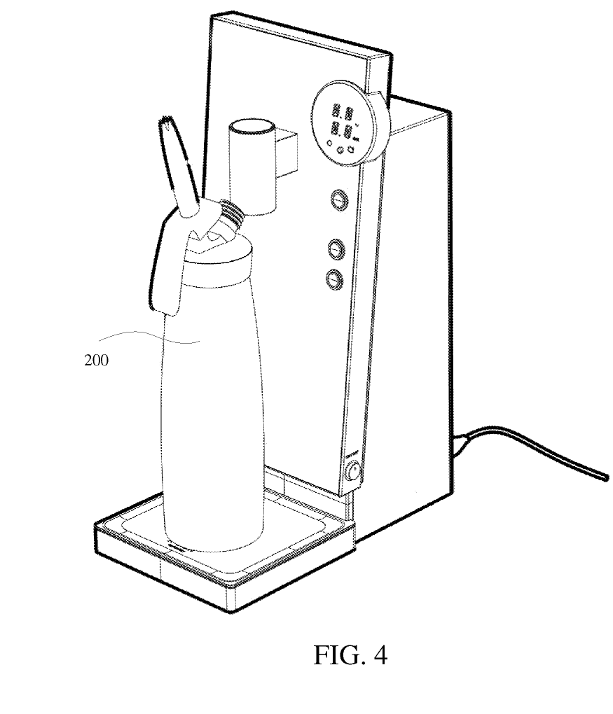

FIGS. 1-5 show internal components of the nitro beverage device. FIG. 4 is a schematic structural diagram of a nitro beverage device and a gas cylinder according to this application. The gas cylinder 200 is configured to receive nitrogen and contain the beverage. The nitro beverage device according to this application includes: an air pump 110, configured to draw in air and compress the air; an oil-water separator 130 configured to filter out impurities in the compressed air; a switching module, configured to transmit filtered air to a first molecular sieve (adsorption column or PSA(pressure swing adsorption)) 140 via a first path, so that the first molecular sieve 140 performs absorption and release operations to separate the nitrogen from the air, the switching module being further configured to transmit the filtered air to a second molecular sieve 150 via a second path when the first molecular sieve 140 performs the release operation; a third throttle valve, configured to control a pressure value of the generated nitrogen, and control the nitrogen to be transmitted to a pressure sensor; and a control unit, configured to determine, based on the pressure value of the nitrogen, whether the pressure value of the nitrogen reaches a user preset pressure value.

The control unit is configured to: control starting and pausing of operating of the components inside the nitro beverage device, and when operating is started, control the air pump to start to extract external air into the interior of the nitro beverage device, where the air pump continuously compresses air to generate air pressure when the air pump is operating. Because the air pump needs lubricating oil to prevent wear during operation, the drawn-in air easily carries oil drops. Therefore, a subsequent oil-water separator is needed to separate the oil drops and water drops from the drawn-in air, so that the compressed air is preliminarily filtered. Compressed air after preliminarily filtering and purification enters the switching module. The switching module is a two-position five-port electromagnetic valve (referred to as a first electromagnetic valve below) that has two paths respectively connected to the first molecular sieve 140 and the second molecular sieve 150. The control unit controls the first path to be conducted, so that the air enters the first molecular sieve for the absorption and release operations, thereby separating the nitrogen from the air. In this process, the first molecular sieve 140 selectively adsorbs, under a high pressure state, oxygen and water in the air, so that the nitrogen can be separated. When absorption of the first molecular sieve 140 reaches saturation, the control unit controls the first electromagnetic valve 190 to switch to conducting the second path and shutting off the first path, so that the air filtered by the oil-water separator 130 enters the second molecular sieve 150, and the first molecular sieve 140 is triggered to enter the release stage, to expel the absorbed oxygen and water vapors through an air exhaust.

When performing the absorption operation, the first molecular sieve selectively adsorbs the oxygen and water in the air. Because nitrogen molecules are relatively large, the nitrogen cannot be absorbed. Therefore, the nitrogen can be generated in real time. The generated nitrogen is transmitted to the third throttle valve through an air outlet of the first molecular sieve. The third throttle valve is configured to: control a flow direction of the nitrogen, and control a flow rate of the nitrogen by changing a cross section in a flow path of the nitrogen, to indirectly control the pressure of the nitrogen. The generated nitrogen reaches the pressure sensor after passing through the third throttle valve, and the pressure sensor monitors the pressure value of the arriving nitrogen in real time and transmits the value to the control unit. If the nitrogen pressure value falls within a preset safe pressure value range, the nitrogen is outputted from the nozzle to the gas cylinder. After being generated, the nitrogen is directly outputted to the gas cylinder or a beverage container, and the nitrogen can be continuously generated in a preparation process, so that a speed and convenience of outputting the nitrogen are improved, and an operation process of preparing the nitro beverage is simplified and efficiency is improved.

In another embodiment of this application, the control unit is configured to receive a user instruction, to be specific, a user preset pressure value. For example, the user may expect nitrogen at 8 bar (bar, a pressure unit). After receiving a pressure value from the pressure sensor, the control unit determines whether the pressure value reaches the user preset pressure value. If the pressure value detected by the pressure sensor does not reach the user preset value, the control unit controls the air pump to continue operating, to extract external air and continue to generate nitrogen. If the pressure value reaches the user preset pressure value, the control unit controls the nitrogen to be outputted to from the nozzle the gas cylinder according to the user preset pressure value.

In this application, air outlets of main components, to be specific, the first molecular sieve and the second molecular sieve, for generating the nitrogen are directly connected to the third throttle valve, and after the third throttle valve regulates and controls generation of the nitrogen, if a pressure value reaches the user preset value and is less than the preset safe pressure value, the nitrogen can be directly outputted from the nozzle. In this way, the air storage tank is omitted, and an operating mode of using the nitrogen right after generation is implemented, so that the internal structure is simplified while high efficiency is ensured, and the operation is more convenient.

Further, the first molecular sieve and the second molecular sieve in this application operate alternately, and one performs an absorption operation and the other performs release and regeneration operations, thereby ensuring sustainability of the generation of the nitrogen. For example, from adsorption of the first molecular sieve reaches saturation to regeneration of the first molecular sieve, the first molecular sieve needs to release water vapors and oxygen. In this process, the air pump continuously draws in air, and the second molecular sieve generates nitrogen to be used for manufacturing a next beverage. Such an alternate operating mechanism not only improves efficiency of supply of the nitrogen, but also ensures continuity and stability of manufacturing the foamy beverage.

Still referring to FIGS. 1-3, a cooling pipe 120 is further disposed between the air pump 110 and the oil-water separator 130, and the cooling pipe is configured to cool the air compressed by the air pump.

Mechanical thermal energy is generated during operation of the air pump, and a temperature of the compressed air also increases due to compression. An excessively high temperature of air that enters the first molecular sieve or the second molecular sieve leads to reduction in performance of the molecular sieve, and generation efficiency and quality of the nitrogen are affected. Therefore, in this application, the cooling pipe is disposed between the air pump and the oil-water separator, so that the compressed air can be effectively cooled, to prevent an excessively high temperature from negatively affecting subsequent processes of manufacturing the nitrogen. The cooling pipe may be a copper pipe, or made of another material having good heat conduction performance, to ensure rapid and effective heat removal.

Still referring to FIGS. 1-3, a first three-way valve is disposed between the oil-water separator 130 and the first electromagnetic valve 190 in this application, and the first three-way valve is connected to a pressure relief port. The control unit controls, when responding to a start operating instruction of a user, the first three-way valve to transmit the filtered air to the first electromagnetic valve 190. The control unit controls, when responding to a stop instruction of a user, the first three-way valve to cause the air drawn by the air pump to flow out through the pressure relief port.

When the user sends the start operating instruction , the control unit controls opening and closing of the first three-way valve, to change the flow direction of the air. After receiving the start operating instruction of the user, the control unit transmits the air drawn in by the air pump to the first electromagnetic valve 190 through the oil-water separator and the first three-way valve.

When the control unit receives the stop instruction of the user, the control unit controls the first three-way valve to conduct a path to a pressure relief port connected to the first three-way valve and expel, through the pressure relief port, the air drawn in by the air pump. It is considered that directly pausing operation of the air pump to respond to the stop instruction of the user may cause a sudden change in a pressure inside the nitro beverage device, and may damage the air pump and other components. Especially if the air pump is frequently stopped at a high pressure, a service life of the air pump may be reduced or a fault may be caused. By using the first three-way valve and the pressure relief port, the user instruction can be responded to more flexibly and quickly, and pressure can be managed or released more safely and effectively, to protect the air pump from being damaged.

In an embodiment of this application, the nitro beverage device further includes a second three-way valve. The second three-way valve is connected to a safety valve. The second three-way valve also changes a flow path of the air. One path is used for transmitting air to an air inlet (identified as 1 in FIG. 1) of the first electromagnetic valve 190, and the other path releases redundant pressure by using the safety valve when air pressure is greater than the preset safety pressure value, thereby ensuring safety performance of the nitro beverage device.

In the foregoing embodiment provided with the first three-way valve, the second three-way valve is disposed between the first three-way valve and the first electromagnetic valve 190. The preset safe pressure value in this embodiment of this application is 10 bar. 10 bar is selected as the preset safe pressure value to ensure that the system can safely process possible pressure fluctuation while operating efficiently. When a system pressure exceeds 10 bar, a safety valve automatically opens and releases redundant pressure until the pressure of air inside the apparatus recovers to a safe level.

Further, as shown in FIG. 1, the first molecular sieve includes a first throttle valve, the second molecular sieve includes a second throttle valve, and the first throttle valve and the second throttle valve are connected to a third three-way valve; and during an absorption operation of the first molecular sieve, the separated nitrogen enters the nozzle via the third three-way valve; and during a release operation, the first molecular sieve sequentially releases absorbed oxygen and water vapors through an air exhaust.

In the nitro beverage device of this application, when 1 and 2 of the first electromagnetic valve 190 are conducted, the compressed air is guided to enter the first molecular sieve, and in this case, the first molecular sieve enters an absorption operation stage. In a high-pressure state (for example, 6 bar), the molecular sieve selectively adsorb oxygen and water vapors in the air, and because of a large molecular size of the nitrogen, the nitrogen cannot enter a microporous structure of the molecular sieve, and thereby realizing separation. The separated nitrogen then passes through the throttle valve, flows to the third three-way valve after pressure and flow rate regulation, then passes through a filtering apparatus, and is finally collected or directly used in manufacturing of the foamy beverage.

When absorption of the first molecular sieve reaches a saturation state, the pressure needs to be reduced to normal pressure or even a vacuum state (for example, 1 bar or 0.1 bar) to implement desorption, so that the absorbed oxygen and water vapors are released and are expelled through the air exhaust 4. Once the first molecular sieve enters the released state, the control unit controls the first electromagnetic valve to switch to shutting off 1 and 2 and conducting 1 and 3, so that the air flows into the second molecular sieve, and the second molecular sieve starts the absorption operation of the second molecular sieve, to generate nitrogen through separation to be outputted to the nozzle through the third three-way valve. When the second molecular sieve also reaches saturation, oxygen and water vapors desorbed by the second molecular sieve are expelled through the air exhaust 5.

Each molecular sieve is equipped with an independent throttle valve, and two throttle valves are connected through the third three-way valve, so than independent control on each of the molecular sieves can be implemented. By using the throttle valve and the third three-way valve, the pressure between the two molecular sieves can be balanced, to ensure a stable transition between the pressure between the two molecular sieve in a switching stage, thereby avoiding impact of the pressure fluctuation on the performance and the service life of the molecular sieves.

Still further, in this embodiment of this application, because the first molecular sieve 140 and the second molecular sieve 150 operate alternately, when one molecular sieve performs the absorption operation, the other molecular sieve performs the release and regenerating operations. To ensure that the molecular sieve performing the desorption (release) and regeneration operations can more quickly and effectively release air and water vapors that are absorbed by the molecular sieve, referring to a dashed-line arrow part in FIG. 1, a part of the nitrogen N₂ generated by the molecular sieve performing the absorption operation is transmitted to the molecular sieve performing the release operation through the third three-way valve and a corresponding throttle valve (the first or second throttle valve). Because of backflush of the nitrogen, release of oxygen and water vapors that are absorbed inside the molecular sieve that receives the part of the nitrogen is accelerated, regeneration efficiency of the molecular sieve is optimized, and it is ensured that the molecular sieve can operate efficiently again in a next absorption period. The throttle valve is further configured to regulate a pressure of backflush air and control the nitrogen to enter the molecular sieve in the release state.

The control panel 180 includes an operation key 182 and a display panel 181; the operation key 182 is used for a user to set the user preset pressure value and start or pause operating of a device; and the display panel 181 is configured to display a device state and the user preset pressure value.

A filtering apparatus, a third throttle valve, and a pressure sensor are sequentially disposed between the third three-way valve and the nozzle. The filtering apparatus is configured to ensure purity of the nitrogen. The third throttle valve is configured to adjust a pressure value of the nitrogen. The pressure sensor is configured to detect an adjusted pressure value of the nitrogen. The control unit is configured to inject, when the pressure value of the nitrogen satisfies a user preset pressure value, the nitrogen from the nozzle into the gas cylinder according to the user preset pressure value. Beverages in the gas cylinder are mixed with the nitrogen to generate abundant froth.

Because the nitrogen separated by the molecular sieve may be attached with trace amounts of impurities on the molecular sieve, the setting of the filtering apparatus can remove these impurities, to ensure the nitrogen pure and avoid affecting quality of the foamy beverage. The filtering apparatus may be a filter mesh, a filter membrane, a filter element, or the like made of materials such as borosilicate and polyester microfiber, and the filtering apparatus may be periodically disassembled and replaced.

The nitro beverage device according to this embodiment of this application can quickly and conveniently produce beverages with a particular froth feature according to personalized requirements of users, thereby improving user experience, and also ensuring quality and consistency of the beverages. In addition, the nitro beverage device according to this embodiment of this application implements, by using the operation panel and the control unit, a function of using nitrogen right after generating the nitrogen, thereby eliminating the manner in the existing technology in which air storage tanks and buffer tanks are required. Such a design enables the operation manner to be faster and more convenient, and a device structure is more compact, which is more convenient for daily household use or various use environments.

It should be noted that the user may control operating and pause of the nitro beverage device and setting of froth requirements by using keys on an operation panel or touch buttons on a display panel 181. The user may also perform remote operations by using a mobile phone application connected to the nitro beverage device through Bluetooth, thereby improving flexibility and convenience of the device.

The nitro beverage device according to this embodiment has a characteristic of a one-click operation. For example, after starting the device to make nitrogen coffee, a user may leave for a moment to make breakfast or make other preparations. To ensure that the user can intuitively learn of an operating status of the nitro beverage equipment, a prompt apparatus is set to provide instant feedback to the user based on different statuses of the device.

The prompt apparatus includes an indicator prompt or a voice prompt. The indicator changes light colors in different device states to notify the user of a state that the device is in. When the user is far away from the device, the user can still determine, by observing a color change of the indicator from far away, whether the beverage is ready, or whether the device is faulty when making the beverage.

Similarly, the voice prompt broadcasts current operating status of the device and pre-recorded voice information in different device states, and explicitly notifies the user of the current operating progress or status. For example, the device may play a voice when starting to make a foamy beverage, to inform the user of "Making starts"; when your beverage is completed, "Making completes, your beverage is ready" is played; or when a fault is detected, "An error occurred, Please check the device" is played.

In addition, the operating status broadcast by the voice prompt may further include states such as "Inflating", "Inflation completed", "Making completed", "Fault checking", and "Filter replacement required", so as to provide more comprehensive user guidance.

Furthermore, an electromagnetic valve used in the device may be configured as a normally open valve or a normally closed valve. The control unit may adopt a printed circuit board (PCB) or a flexible printed circuit board (FPC), thereby improving the cost performance of the foamy beverage device and its internal components.

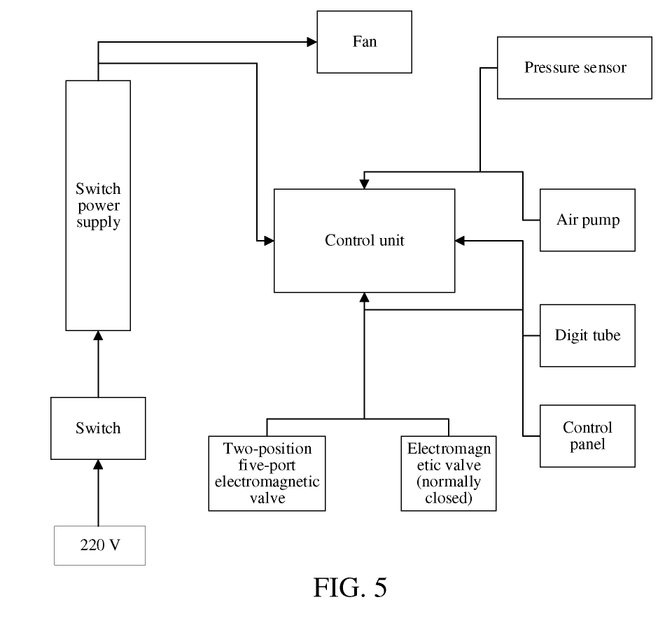

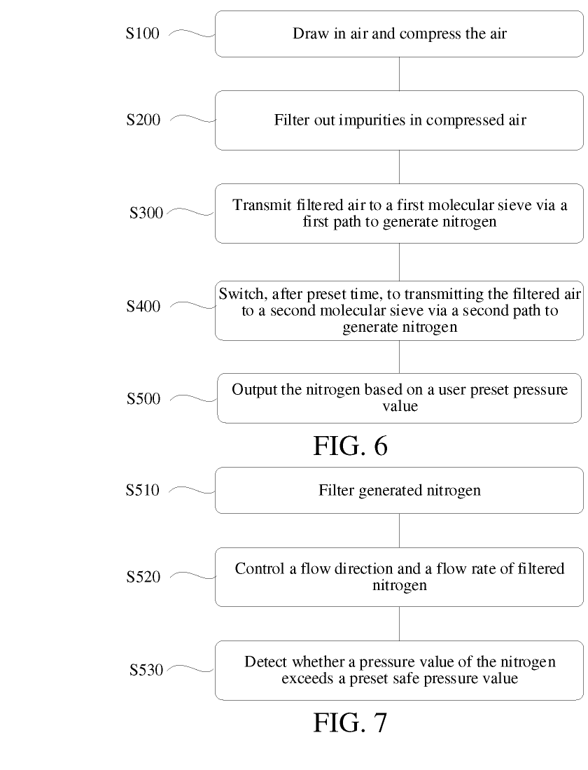

According to another aspect of this application, a nitrogen preparation method is further provided, applied to a nitro beverage device. As shown in FIGS. 5 and 6, the nitrogen preparation method includes the following steps:

S100: Draw in air and compress the air.

S200: Filter out impurities in compressed air.

S300: Transmit filtered air to a first molecular sieve via a first path to generate nitrogen.

S400: Switch, after preset time, to transmitting the filtered air to a second molecular sieve via a second path to generate nitrogen.

In this embodiment of this application, time of an absorption operation and desorption and regeneration of each of the molecular sieve is 25 seconds (s).

In other words, preset absorption time is 25 seconds. After absorption of the first molecular sieve reaches 25 seconds, the control unit controls the switching module to shut off the first path (1 and 2), and conduct the second path (1 and 3), to transmit the filtered air to the second molecular sieve, and start a process of generating the nitrogen by the second molecular sieve.

In the switching process, the control unit precisely controls conducting/shutting off of the two paths of the switching module, and implements a switching operation of two molecular sieves through time sequence control. In this way, when the first molecular sieve completes absorption and starts desorption, the second molecular sieve immediately starts the absorption operation, to continuously generate the nitrogen.

S500: Output the nitrogen according to a user preset pressure value.

As shown in FIG. 7, step S500 further includes the following steps:

S510: Filter the generated nitrogen.

S520: Control a flow direction and a flow rate of filtered nitrogen.

S530: Detect whether a pressure value of the nitrogen exceeds a preset safe pressure value.

Further, it is ensured that the pressure of the nitro beverage device is stable during operation, and the pressure sensor detects the pressure value of the nitrogen before the nitrogen is outputted. It is avoided that the pressure value of the nitrogen exceeds a preset safe pressure value, to avoid risks caused by an excessively high pressure of the system. This security mechanism further ensures security and reliability of device operation.

In this embodiment of this application, the nitrogen passing through filtering of the filtering apparatus and flow control may be directly outputted to a gas cylinder or a beverage container. Alternatively, the control unit determines, based on the pressure value of the nitrogen detected by the pressure sensor, whether the pressure value of the nitrogen reaches a user preset pressure value, and if the pressure value reaches the user preset pressure value, the control unit controls the nitrogen to be injected from the nozzle into the gas cylinder according to the user's pressure value.

Before step S200, the method further includes a step of automatically relieving pressure when a pressure value of the compressed air is greater than the preset safe pressure value.

The user first places the gas cylinder 200 on a carrier platform 160, to ensure that the gas cylinder 200 is stable and easy to operate. The gas cylinder is configured to receive the nitrogen from the nitrogen preparing method and contain the final foamy beverage. The beverage in the gas cylinder 200 may be various types of beverages, for example, beer, wine, juice, tea, and cold brew coffee.

The user sets a required froth feature by using the control panel 180, that is, sets a user preset pressure value, and then presses a confirm button to confirm the instruction. After receiving the user instruction, the control unit starts the operating state. The air pump starts to extract external air and compress the air. Impurities are removed from the compressed air by the oil-water separator, and then the compressed air enters the first molecular sieve through the first three-way valve, the second three-way valve, and the switching unit, namely, the first electromagnetic valve, to start the manufacturing process of the nitrogen. In this case, the display panel 181 displays that a device state is "Filling nitrogen".

The nitrogen separated by the first molecular sieve sequentially flows through the first throttle valve, the third three-way valve, the filtering apparatus, and the third throttle valve. The pressure value is monitored by using the pressure sensor, and the nitrogen finally reaches the nozzle. The control module determines, based on the pressure value of the nitrogen sensed by the pressure sensor, whether the pressure value reaches the user preset pressure value. If the preset value is reached, the control module controls to inject the nitrogen into the gas cylinder at the user preset pressure value. After the nitrogen injection is completed, the display panel 181 displays "Complete".

In this case, the user may disassemble the gas cylinder from the device, and pours the liquid beverage, that is in the gas cylinder and into which the nitrogen is injected, into another container for drinking or further processing. Subsequently, the user may install and connect the gas cylinder to the nozzle again, to prepare for a next round of foamy beverage preparation.

In this embodiment of this application, time of an absorption operation and desorption and regeneration of each of the molecular sieve is 1 minute. The control unit precisely controls conducting status of the switching module, and implements the switching operation of the two molecular sieves through time sequence control, to continuously generate the nitrogen. This design not only improves efficiency of nitrogen generation, but also ensures continuity and stability of the nitrogen generation process, meets a continuity requirement of making foamy beverages for nitrogen supply, implements efficient and continuous nitrogen generation, and is applicable to making foamy beverages in a home environment or a small commercial environment.

The foregoing descriptions are merely preferred embodiments of this application, and are not intended to limit this application in any form. The protection scope of this application shall be subject to the protection scope of the claims. Although this application has been disclosed above through the exemplary embodiments, the embodiments are not intended to limit this application. Any person skilled in the art can make some variations or modifications to the technical content disclosed above without departing from the scope of the technical solutions of this application, to obtain equivalent embodiments with equivalent changes. However, any simple alteration, equivalent change or modification made to the foregoing embodiments based on the technical essence of this application without departing from the content of the technical solutions of this application shall fall within the scope of the technical solutions of this application.

What is claimed is:

1. A nitrogen preparation method, comprising the following steps:
drawing in air and compressing the air;
filtering out impurities in compressed air;
transmitting filtered air to a first molecular sieve via a first path to generate nitrogen;
switching, after preset time, to transmitting the filtered air to a second molecular sieve via a second path to generate nitrogen; and
outputting the nitrogen according to a user preset pressure value.

2. The nitrogen preparation method according to claim 1, wherein the "outputting the nitrogen according to a user preset pressure value" further comprises:
filtering the generated nitrogen;
controlling a flow direction and a flow rate of filtered nitrogen; and
detecting whether a pressure value of the nitrogen exceeds a preset safe pressure value.

3. The nitrogen preparation method according to claim 1, further comprising:
automatically relieving pressure when a pressure value of the compressed air is greater than the preset safe pressure value.

4. A nitro beverage device, comprising:
an air pump, configured to draw in air and compress the air;
an oil-water separator, configured to filter out impurities in compressed air;
a switching module, configured to transmit filtered air to a first molecular sieve via a first path,
the switching module being further configured to switch, after preset time, to transmitting the filtered air to a second molecular sieve via a second path; and
a nozzle and a gas cylinder that are detachably connected, the nozzle being configured to fill the nitrogen into the gas cylinder according to a user preset pressure value.

5. The nitro beverage device according to claim 4, wherein a first three-way valve is disposed between the oil-water separator and the switching module, and the first three-way valve is connected to a pressure relief port;
the first three-way valve transmits the filtered air to the switching module when responding to a start operating instruction of a user; and
the first three-way valve is controlled, when responding to a stop instruction of a user, to cause the air drawn by the air pump to flow out through the pressure relief port.

6. The nitro beverage device according to claim 5, wherein a second three-way valve is disposed between the first three-way valve and the switching module, the second three-way valve is connected to a safety valve, and the second three-way valve is further configured to transmit the air to the switching module; and
the safety valve is configured to relieve pressure when a pressure of the air is greater than the preset safe pressure value.

7. The nitro beverage device according to claim 4, wherein the first molecular sieve comprises a first throttle valve, the second molecular sieve comprises a second throttle valve, and the first throttle valve and the second throttle valve are connected to a third three-way valve; and
during an absorption operation of the first molecular sieve, the separated nitrogen enters the nozzle via the third three-way valve, and/or enters the second molecular sieve sequentially via the third three-way valve and the second throttle valve; and
during a release operation, the first molecular sieve releases oxygen and water vapors through an air exhaust.

8. The nitro beverage device according to claim 4, wherein a filtering apparatus, a third throttle valve, and a pressure sensor are disposed between the third three-way valve and the nozzle;
the filtering apparatus is configured to filter out impurities in the nitrogen;
the third throttle valve is configured to control a pressure value of the nitrogen and control the nitrogen to be transmitted to the pressure sensor; and
the pressure sensor is configured to detect the pressure value of the nitrogen.

9. The nitro beverage device according to claim 8, wherein the control unit is configured to control the nitrogen to enter the gas cylinder through the nozzle when the pressure value of the nitrogen detected by the pressure sensor reaches the user preset pressure value.

10. The nitro beverage device according to claim 4, wherein a cooling pipe is further disposed between the air pump and the oil-water separator, and the cooling pipe is configured to cool the air compressed by the air pump.

11. The nitro beverage device according to claim 7, wherein the nitro beverage device further comprises a control panel and a control unit, the control panel is configured to generate a user instruction, and the control unit is configured to control start/stop or power-off of each component to respond to the user instruction; and
the control panel comprises an operation key and a display panel; the operation key is used for a user to set the user preset pressure value and start or pause operating of a device; and the display panel is configured to display a device state and the user preset pressure value.

12. The nitro beverage device according to claim 7, further comprising a prompting device, wherein the prompting device is configured to inform a user of an operating state of the device; and the prompting device comprises at least one of an indicator light and a voice prompt.
